(19) United States
(12) Patent Application Publication
(10) Pub. No.: US 2008/0318084 A1
(43) Pub. Date: Dec. 25, 2008

(54) White organic light emitting device and display apparatus

(76) Inventors: Sung-hun Lee, Yongin-si (KR); Sang-yeol Kim, Yongin-si (KR); Mu-gyeom Kim, Yongin-si (KR); Jung-bae Song, Yongin-si (KR)

Correspondence Address: ROBERT E. BUSHNELL, 1522 K STREET NW, SUITE 300, WASHINGTON, DC, 20005-1202, US

(21) Appl. No.: 12/078,170

(22) Filed: Mar. 27, 2008

(30) Foreign Application Priority Data
Jun. 22, 2007 (KR) 10-2007-0061873

(51) Int. Cl. C09K 11/00

(52) U.S. Cl. 428/690

(57) ABSTRACT

A white organic light emitting device and a display apparatus and a lighting apparatus including the same. The white organic light emitting device include an anode, a hole transporting layer, a light emitting layer, an electron transporting layer, a cathode, and at least one color stabilizing layer between the light emitting layer and the electron transporting layer.

### CLAIM OF PRIORITY

This application makes reference to, incorporates the same herein, and claims all benefits accruing under 35 U.S.C.§119 from an application for WHITE ORGANIC LIGHT EMITTING DEVICE AND DISPLAY APPARATUS AND LIGHTING APPARATUS COMPRISING THE SAME earlier filed in the Korean Intellectual Property Office on 22 Jun. 2007 and there duly assigned Serial No. 10-2007-0061873.

### BACKGROUND OF THE INVENTION

1. Field of the Invention

The present invention relates to a light emitting device and apparatuses including the same, and more particularly, to a white organic light emitting device minimizing color change according to brightness and a display apparatus and a lighting apparatus including the same.

2. Description of the Related Art

Organic Light Emitting Devices (OLEDs) are self emissive display devices that use light generated by combining electrons and holes supplied to a fluorescence or phosphorescence organic compound thin film (hereinafter, an organic thin film).

A white OLED can emit white light, and can be used as a paper-thin source, a backlight for a liquid crystal display device, or a full color display device that employs a color filter.

Generally, the OLED has a structure in which an anode, a hole transporting layer, a light emitting layer, an electron transporting layer, and a cathode are sequentially formed on a substrate. The light emitting layer includes a red light emitting layer, a green light emitting layer and a blue light emitting layer. A hole blocking layer may be interposed between the light emitting layer and the electron transporting layer, and an electron blocking layer may be interposed between the light emitting layer and the hole transporting layer.

However, conventional white OLEDs have a problem of serious color change based on applied voltages because of electric field dependent mobility which is an inherent characteristic of an electron transporting layer, a hole transporting layer and/or a hole blocking layer. That is, charge mobility of the electron transporting layer, the hole transporting layer and/or the hole blocking layer largely varies according to voltages applied between the anode and the cathode. This will now be described in more detail.

Charge mobility μ of an organic semiconductor such as the electron transporting layer, the hole transporting layer and the hole blocking layer can be calculated by Equation 1 below.

μ=μ₀exp(α\sqrt{E}) Equation 1

According to Equation 1, charge mobility μ exponentially increases as electric field E increases. Here, α and μ₀ are constants determined according to a specific material.

FIG. 1 shows a graph illustrating charge mobility of Alq3 layer as an electron transporting layer and α-NPD layer as a hole transporting layer according to electric field.

Referring to FIG. 1, electron mobility of Alq3 layer as an electron transporting layer increases faster than hole mobility of α-NPD layer as a hole transporting layer. This is because Alq3 layer as an electron transporting layer has a greater α (same as α of Equation 1) than α-NPD layer as a hole transporting layer.

If the electron transporting layer or the hole transporting layer is doped at a high concentration, the problem of serious color change due to electric field dependent mobility of the electron transporting layer or the hole transporting layer can be reduced since electrical conductivity thereof increases. However, even when the electron transporting layer and the hole transporting layer are doped at a high concentration, a problem of color change according to applied voltages may occur because of electric field dependent mobility of the hole blocking layer and/or the electron blocking layer. In particular, problem of color change caused by the hole blocking layer is serious since the hole blocking layer has a greater α value than that of the electron blocking layer.

Thus, it is difficult to obtain uniform three primary colors within the conventional white OLEDs.

### SUMMARY OF THE INVENTION

The present invention provides a white organic light emitting device (OLED) minimizing color change according to applied voltages.

The present invention also provides a display apparatus including the white OLED.

The present invention also provides a lighting apparatus including the white OLED.

According to an aspect of the present invention, there is provided a white OLED including a layer (a color stabilizing layer) which can offset charge mobility change of an electron transporting layer and/or a hole blocking layer according to voltages. The constitution of the white OLED is as follows.

The white organic light emitting device includes an anode, a hole transporting layer, a light emitting layer, an electron transporting layer and a cathode. At least one color stabilizing layer is interposed between the light emitting layer and the electron transporting layer.

A hole blocking layer may be interposed between the light emitting layer and the electron transporting layer.

The color stabilizing layer may be interposed at least one of between the light emitting layer and the hole blocking layer and between the hole blocking layer and the electron transporting layer.

A mobility change ratio of the color stabilizing layer according to electric field is different from a mobility change ratio of the electron transporting layer and/or the hole blocking layer due to the electric field.

The color stabilizing layer may include at least one compound selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

The color stabilizing layer may be Alq3 [tris-(8-hydroxy-quinolinato)-aluminum] layer.

A charge mobility of the color stabilizing layer may be in the range of 10⁻³ to 10⁻⁶ cm²/Vs.

A highest occupied molecular orbital (HOMO) level of the color stabilizing layer may be in the range of 5.3 to 6.5 eV.

A lowest unoccupied molecular orbital (LUMO) level of the color stabilizing layer may be in the range of 2.6 to 3.2 eV.

The hole blocking layer may include at least one compound selected from the group consisting of an oxadiazole derivative, a triazole derivative, a phenanthroline derivative, 2,9-Dimethyl-4,7-diphenyl-1,10-phenanhro-line (BCP) and an aluminum complex.

The hole blocking layer may be Balq [aluminum(III) bis(2-methyl-8-quinolinato) 4-phenylphenolate] layer.

A hole injecting layer may further be interposed between the anode and the hole transporting layer.

An electron injecting layer may further be interposed between the cathode and the electron transporting layer.

An electron blocking layer may further be interposed between the hole transporting layer and the light emitting layer.

The light emitting layer may be a two-layer structure including one of a red light emitting layer and a yellow light emitting layer, and a blue light emitting layer, or a three-layer structure including a red light emitting layer, a blue light emitting layer and a green light emitting layer. In the light emitting layer having the three-layer structure, the red light emitting layer, the blue light emitting layer and the green light emitting layer may be sequentially stacked, but the present invention is not limited thereto.

When the light emitting layer has a structure in which the red light emitting layer, the blue light emitting layer and the green light emitting layer are sequentially stacked, an interlayer buffer layer may further be interposed between the red light emitting layer and the blue light emitting layer and/or between the blue light emitting layer and the green light emitting layer.

Each of the red light emitting layer, the blue light emitting layer and the green light emitting layer may include an organic host and a light emitting dopant.

The light emitting dopant may be an organic molecule or organometallic complex having fluorescence or phosphorescence characteristic. The amount of the light emitting dopant in each of the red light emitting layer, the blue light emitting layer and the green light emitting layer may be in the range of 0.2 to 30 wt %.

The anode may include a conductive material having a high work function. For example, the anode may be formed of at least one material selected from the group consisting of indium zinc oxide (IZO), indium tin oxide (ITO), SnO₂, ZnO, Ni, Ag, Au, Pt, Pd, Rh, Ru, Ir, W, Mo, Cr, Ta, Nb and an alloy thereof. Further, the anode may have a single layer or a multi layers.

The hole transporting layer may include at least one compound selected from the group consisting of an oxadiazole compound having an amino substituent, a triphenylmethane compound having an amino substituent, a tertiary compound, a hydrazone compound, a pyrazoline compound, an enamine compound, a styryl compound, a stilbene compound, and a carbazole compound.

The hole transporting layer may or may not include a p-type impurity. Here, the p-type impurity may be artificially added to increase electrical conductivity of the hole transporting layer. The LUMO level of the p-type impurity may be lower than the HOMO level of the hole transporting layer.

When the hole transporting layer includes the p-type impurity, the amount of the p-type impurity may be in the range of 0.1 to 30 wt %.

The electron transporting layer may include at least one compound selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

The electron transporting layer may or may not include an n-type impurity. The n-type impurity may be artificially added to increase electric conductivity of the electron transporting layer. The HOMO level of the n-type impurity may be higher than the LUMO level of the electron transporting layer.

When the electron transporting layer includes the n-type impurity, the amount of the n-type impurity may be in the range of 0.1 to 50 wt %.

The cathode may be formed of a conductive material having a low work function. For example, the cathode may be formed of at least one selected from the group consisting of Li, Mg, Ca, Ag, Al, In, ITO, IZO and an alloy thereof. Further, the cathode may have a single layer of a multi layers.

An electron injecting layer may be interposed between the cathode and the electron transporting layer. The electron injecting layer may be a metal compound layer including halogen or oxygen.

According to another aspect of the present invention, there is provided a full color display apparatus including a white OLED according to the present invention and a color filter.

According to another aspect of the present invention, there is provided a liquid crystal display apparatus including a white OLED according to the present invention as a backlight unit.

According to another aspect of the present invention, there is provided a lighting apparatus including a white OLED according to the present invention as a light source.

According to the present invention, a white OLED which can minimize or inhibit color change according to applied voltages can be realized, and a display apparatus and a lighting apparatus including the same can also be realized.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 shows a graph illustrating charge mobility of Alq3 layer as an electron transporting layer and α-NPD layer as a hole transporting layer according to electric field;

FIGS. 2 and 3 show cross-sectional views of white OLEDs according to first and second embodiments of the present invention;

FIGS. 4 and 5 show cross-sectional views of white OLEDs according to first and second comparative examples;

FIGS. 6 and 7 show graphs of emission spectrum of white OLEDs according to first and second embodiments of the present invention;

FIGS. 8 and 9 show graphs of emission spectrum of white OLEDs of FIGS. 4 and 5;

FIGS. 10 and 11 show graphs of color coordinates of white OLEDs according to first and second embodiments of the present invention;

FIGS. 12 and 13 respectively show graphs of color coordinates of white OLEDs of FIGS. 4 and 5.

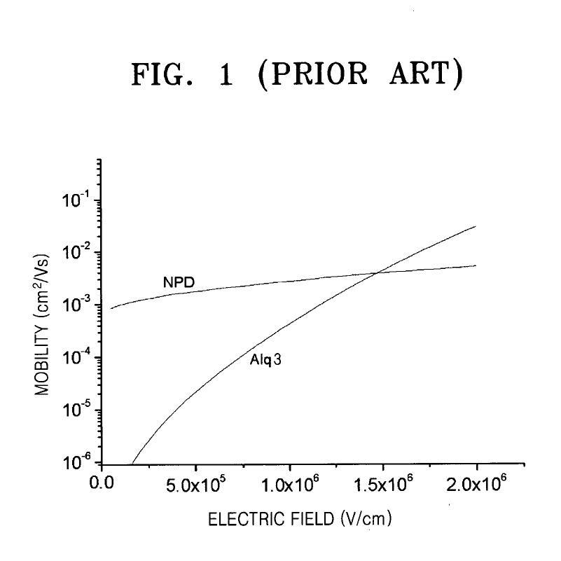

### DETAILED DESCRIPTION OF THE INVENTION

Hereinafter, the present invention will now be described more fully with reference to the accompanying drawings, in which exemplary embodiments of the invention are shown. In the drawings, the width and thickness of layers and regions are exaggerated for clarity.

### Embodiment 1

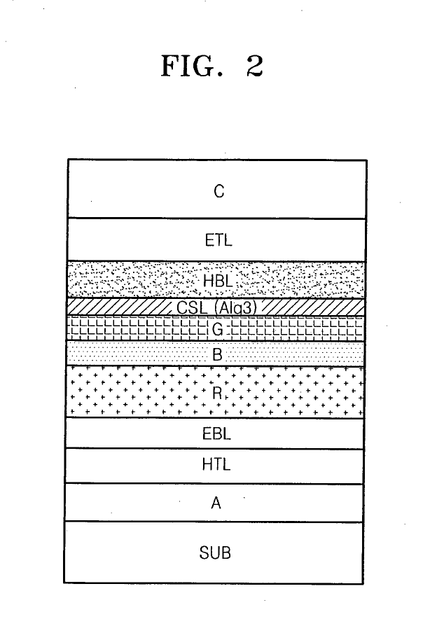

FIG. 2 shows a cross-sectional view of a white organic light emitting device (OLED) according to a first embodiment of the present invention.

Referring to FIG. 2, an anode A is formed on a transparent substrate SUB such as a glass substrate. The anode A is an indium zinc oxide (IZO) layer. The anode A can also be formed of a material other than IZO. For example, the anode A may be formed of at least one selected from the group consisting of IZO, indium tin oxide (ITO), SnO₂, ZnO, Ni, Ag, Au, Pt, Pd, Rh, Ru, Ir, W, Mo, Cr, Ta, Nb and an alloy thereof. Further, the anode A may have a single layer or a multi layers. Surfaces of the anode A and the substrate SUB were washed with a neutral detergent, de-ionized (DI) water, and isopropyl alcohol (IPA), and treated with ultraviolet rays and ozone.

A hole transporting layer (HTL) and an electron blocking layer (EBL) are sequentially formed on the anode A. The HTL may include at least one compound selected from the group consisting of an oxadiazole compound having an amino substituent, a triphenylmethane compound having an amino substituent, a tertiary compound, a hydrazone compound, a pyrazoline compound, an enamine compound, a styryl compound, a stilbene compound, and a carbazole compound, and may have a thickness in the range of 100 to 1000 Å. The HTL may include a p-type impurity to improve electrical conductivity. Here, the amount of the p-type impurity may be in the range of 0.1 to 30 wt %. The EBL may be optionally included and may have a thickness in the range of 20 to 300 Å.

A red light emitting layer R having a thickness of about 10 to 300 Å is formed on the EBL. The red light emitting layer R may include a first organic host and a red light emitting dopant. The amount of the red light emitting dopant in the red light emitting layer R may be in the range of 0.2 to 30 wt %. A blue light emitting layer B having a thickness of about 10 to 300 Å is formed on the red light emitting layer R. The blue light emitting layer B may include a second organic host and a blue light emitting dopant. The amount of the blue light emitting dopant in the blue light emitting layer B may be in the range of 0.2 to 30 wt %. A green light emitting layer G having a thickness of about 10 to 300 Å is formed on the blue light emitting layer B. The green light emitting layer G may include a third organic host and a green light emitting dopant. The amount of the green light emitting dopant in the green light emitting layer G is in the range of 0.2 to 30 wt %. The light emitting dopants included in the red light emitting layer R, the blue light emitting layer B and the green light emitting layer G may be organic molecules or organometallic complexes having fluorescence or phosphorescence characteristics.

An interlayer buffer layer (not shown) may further be included between the red light emitting layer R and the blue light emitting layer B and/or between the blue light emitting layer B and the green light emitting layer G. The interlayer buffer layer inhibits energy transfer among the light emitting layers R, B, and G, or inhibits transfer of one of electrons or holes.

A color stabilizing layer (CSL) is formed on the green light emitting layer G. The CSL is formed of tris-(8-hydroxy-quinolinato)-aluminum (Alq3), and has a thickness of about 20 Å. The thickness of the CSL may be in the range of 5 to 100 Å. A hole blocking layer (HBL) is formed on the CSL. The HBL is formed of aluminum(III) bis(2-methyl-8-quinolinato) 4-phenylphenolate (Balq), and has a thickness of about 110 Å. The thickness of the HBL may be in the range of 5 to 200 Å.

A mobility change ratio of the CSL according to electric field (first change ratio) is different from a mobility change ratio of the HBL according to electric field (second change ratio). For example, the first change ratio is less than the second ratio. Thus, the CSL reduce mobility change according to electric field caused by the HBL. Therefore, color change according to voltages applied to the white OLED, that is, color change according to brightness can be reduced. Further, the CSL functions as a buffer of the HBL, and thus deterioration of the HBL can be inhibited by the CSL. The deterioration rate of the HBL is a critical factor determining lifetimes of the white OLED, and thus inhibition of deterioration of the hole HBL may directly be related to extension of lifetime of the white OLED.

A material to form the CSL is not limited to Alq3, and other materials can be used. The CSL may include at least one compound selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

The charge mobility of the CSL may be in the range of 10⁻³ to 10⁻⁶ cm²/Vs, a highest occupied molecular orbital (HOMO) level and a lowest unoccupied molecular orbital (LUMO) of the CSL may respectively be in the range of 5.3 to 6.5 eV and 2.6 to 3.2 eV.

A material to form the HBL is not limited to Balq, and other materials can be used. The HBL may include at least one selected from the group consisting of an oxadiazole derivative, a triazole derivative, a phenanthroline derivative, 2,9-dimethyl-4,7-diphenyl-1,10-phenanhro-line (BCP) and an aluminum complex.

An electron transporting layer (ETL) is formed on the HBL. The ETL may include at least one selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound and a vinylene compound, and have a thickness in the range of 100 to 1000 Å. The ETL may further include an n-type impurity to improve electric conductivity. Here, the amount of the n-type impurity may be in the range of 0.1 to 50 wt %. A cathode C is formed on the ETL. The cathode C is formed of Al, and has a thickness in the range of 300 to 3000 Å. The cathode C may be formed of a material other than Al. For example, the cathode C may be formed of a material selected from the group consisting of Li, Mg, Ca, Ag, Al, In, ITO, IZO and an alloy thereof. Further, the cathode C may have a single layer or a multi layers.

A hole injecting layer (HIL) may be interposed between the anode A and the HTL, and an electron injecting layer (EIL) may be interposed between the ETL and the cathode C, even though they are not disclosed herein. The EIL may be a metal compound layer including halogen or oxygen, such as a LiF layer.

### Embodiment 2

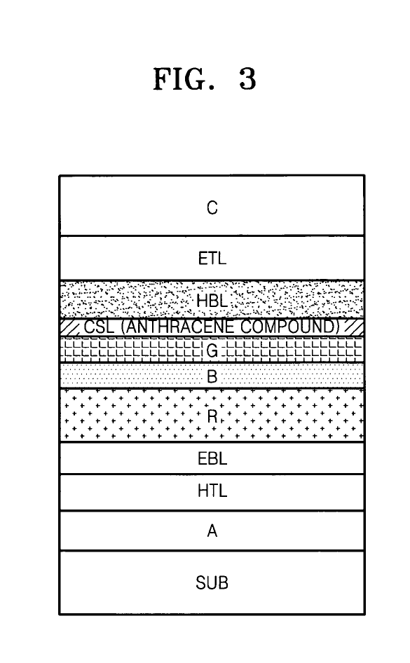

FIG. 3 shows a cross-sectional view of a white OLED according to a second embodiment of the present invention.

The first and second embodiments are distinguished from each other by a material to form the CSL. The CSL in the second embodiment is an anthracene compound layer. The other constitutions of the second embodiment are the same as those of the first embodiment of the present invention.

Hereinafter, first and second comparative examples which are comparative to first and second embodiments of the present invention will now be described.

### Comparative Example 1

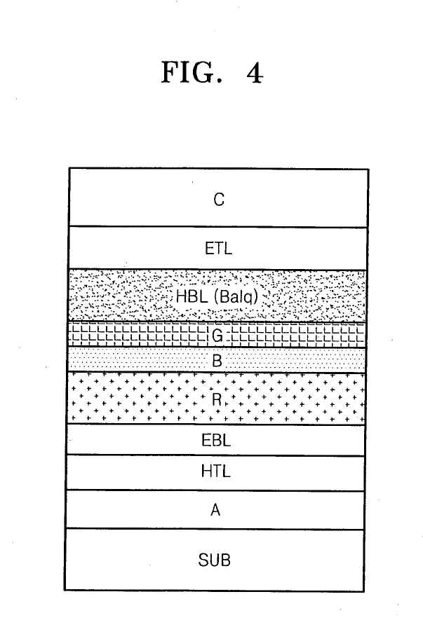

FIG. 4 shows a cross-sectional view of a white OLED according to a first comparative example. In FIGS. 2 and 4, like reference numerals are used to the substantially like elements.

The first embodiment of the present invention and the first comparative example are distinguished from each other by use of the CSL and a thickness of the HBL. Here, the CSL is not used, and the thickness of the HBL is 130 Å. The other constitutions of the first comparative example are the same as those of the first embodiment of the present invention.

### Comparative Example 2

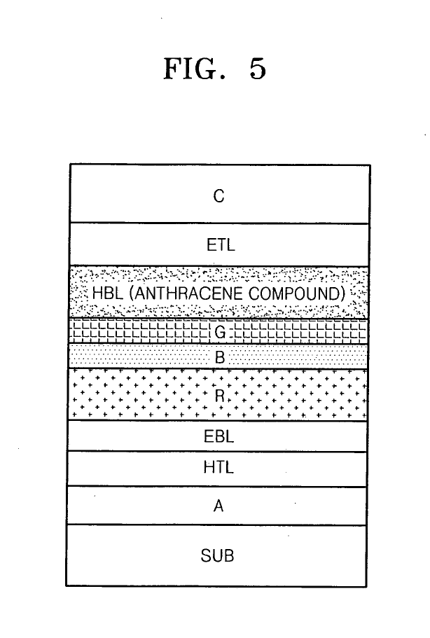

FIG. 5 shows a cross-sectional view of a white OLED according to a second comparative example. In FIGS. 3 and 5, like reference numerals are used to the substantially like elements.

The second embodiment of the present invention and the second comparative example are distinguished from each other by use of the CSL, a material to form the HBL and the thickness of the HBL. Here, the CSL is not used, an anthracene compound layer is used as the HBL, and the thickness of the HBL is 130 Å. The other constitutions of the second comparative example are the same as those of the second embodiment of the present invention.

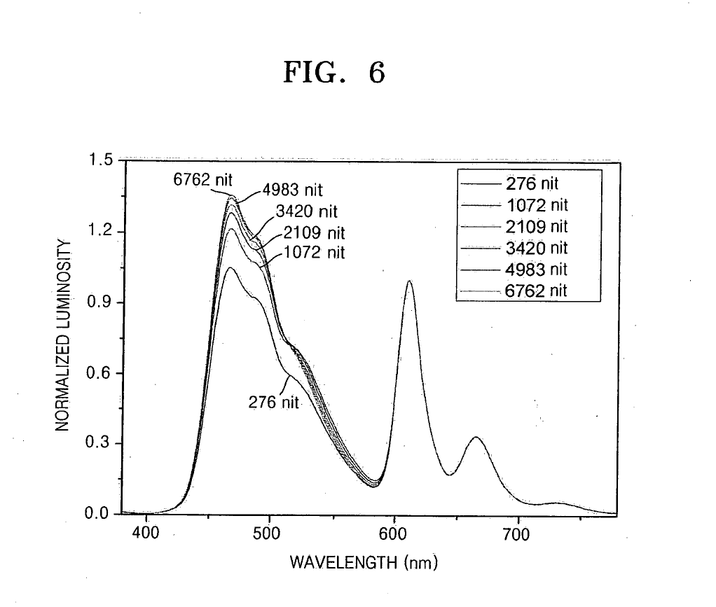

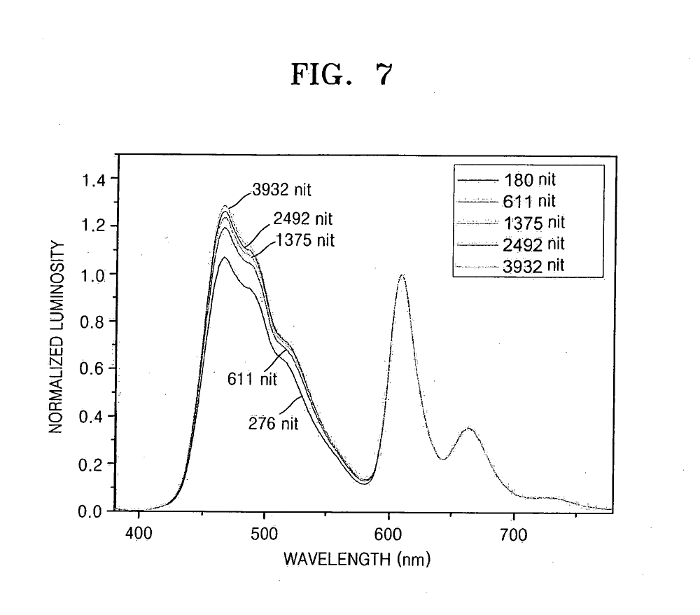

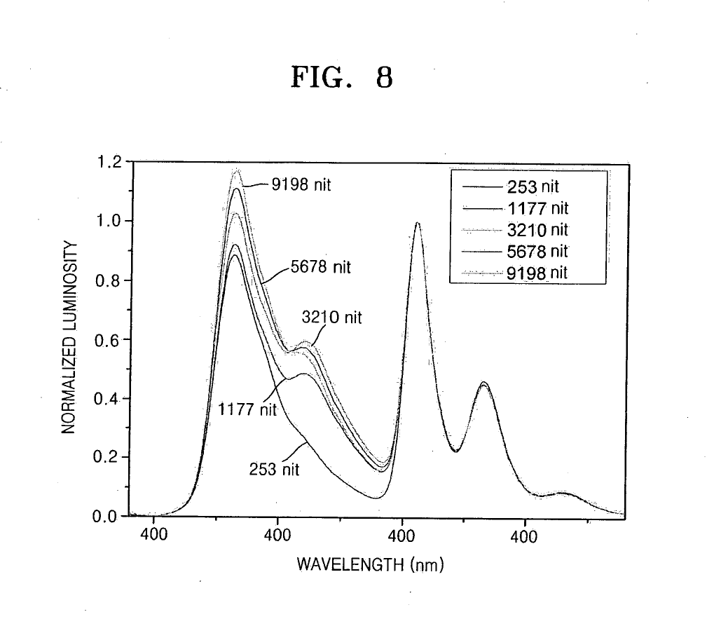

FIGS. 6 and 7 show graphs of emission spectrum of white OLEDs according to first and second embodiments of the present invention. FIGS. 8 and 9 show graphs of emission spectrum of white OLEDs according to first and second comparative examples.

Referring to FIGS. 6 through 9, it can be seen that change of the emission spectrum of the white OLEDs according to embodiments of the present invention is less than the change of the emission spectrum of the white OLEDs according to the comparative examples. In particular, the change of emission spectrum of a green light having a wavelength of about 525 nm was largely reduced by the CSL.

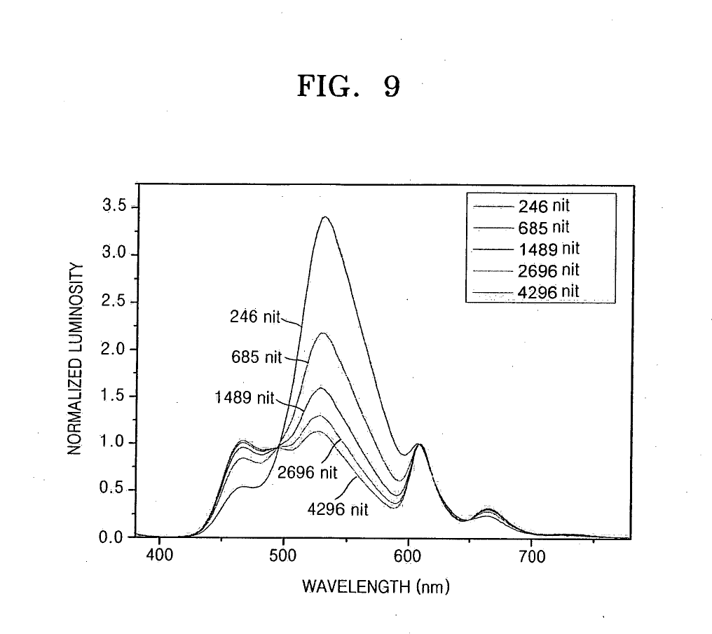

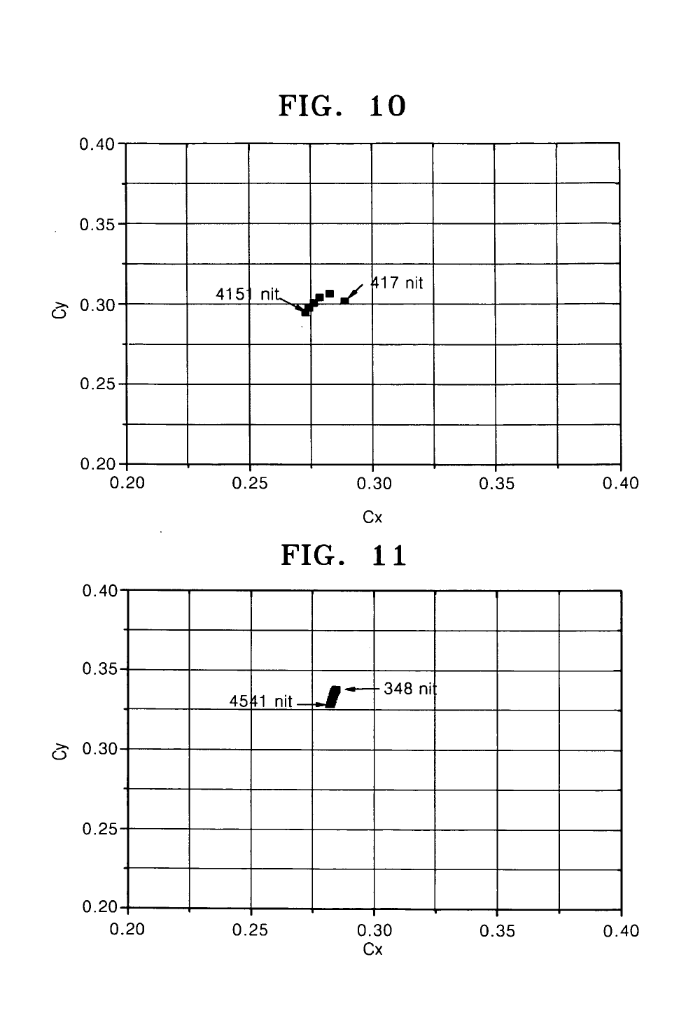

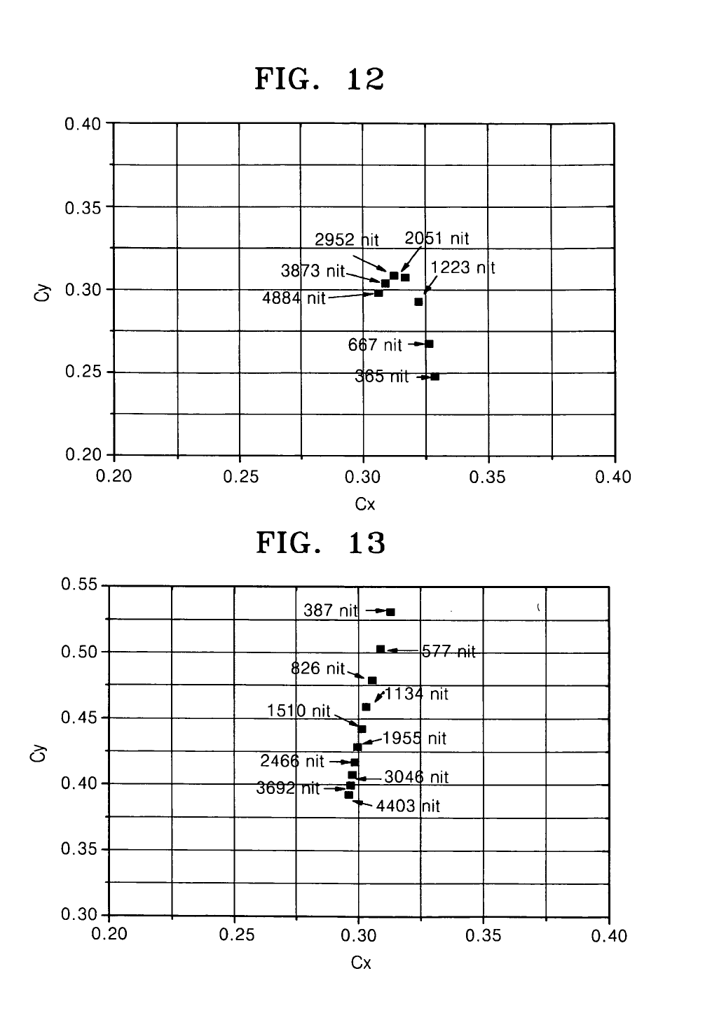

FIGS. 10 and 11 show graphs of color coordinates of white OLEDs according to first and second embodiments of the present invention. FIGS. 12 and 13 respectively show graphs of color coordinates of white OLEDs according to first and second comparative examples. The color coordinates in FIGS. 10 through 13 were measured at a brightness in the range of about 400 to 4000 nit(cd/m²).

Referring to FIGS. 10 through 13, it can be seen that the change of color coordinate of the white OLEDs according to embodiments of the present invention is less than the change of color coordinate of the white OLEDs according to comparative examples.

According to the results of FIGS. 6 through 13, the color change according to the brightness of the white OLED can be reduced by the CSL.

Color coordinate (Cx, Cy), current efficiency (cd/A), quantum efficiency (%), color coordinate variation [Δ(u′,v′)] and lifetime (hour) of the white OLEDs according to the first and second embodiments of the present invention and the first and second comparative examples were measured, and the results are shown in Table 1.

TABLE 1

| | Color | | Current | | | |
|---|---|---|---|---|---|---|
| | coordinate | | efficiency | Quantum | Color | Lifetime |
| | (Cx, Cy) | | (cd/A) | efficiency(%) | coordination | (hour) |
| | (@ 4000 nit) | | (@ 4000 nit) | (@ 4000 nit) | [Δ(u′v′)] | (@ 5000 nit) |
| First embodiment | 0.270 | 0.288 | 14.08 | 8.15 | <0.015 | >1800 |
| Second embodiment | 0.282 | 0.324 | 13.93 | 7.26 | □0.008 | >2000 |
| First comparative | 0.300 | 0.320 | 12.26 | 7.08 | >0.050 | <1300 |
| example | | | | | | |
| Second comparative | 0.296 | 0.396 | 15.73 | 6.73 | >0.053 | <1500 |
| example | | | | | | |

In Table 1, color coordinate, current efficiency and quantum efficiency were measured at a brightness of 4000 nit, and lifetime was measured at a brightness of 5000 nit. Meanwhile, current efficiency was measured when voltages applied to the white OLEDs according to the first and second embodiments of the present invention and the first and second comparative examples were respectively 5.15 V, 5.50 V, 5.33 V and 5.89 V.

Referring to Table 1, it can be seen that variation of color coordinate of the white OLEDs according to embodiments of the present invention is less than variation of color coordinate of the white OLEDs according to comparative examples. Here, variation of color coordinate [A(u′v′)] is calculated using Equations 2 through 4 below.

$$\begin{matrix}Δ ( {u}^{′} {ν}^{′} ) = \sqrt{{( {u}_{4000 nit}^{′} - {u}_{400 nit}^{′} )}^{2} + {( {v}_{4000 nit}^{′} - {v}_{400 nit}^{′} )}^{2}} & Equation 2 \\ {u}^{′} = \frac{4 {C}_{x}}{( - 2 {C}_{x} + 12 {C}_{y} + 3 )} & Equation 3 \\ {v}^{′} = \frac{9 {C}_{y}}{( - 2 {C}_{x} + 12 {C}_{y} + 3 )} & Equation 4\end{matrix}$$

A low variation of color coordinate [Δ(u′v′)] indicates that color change was low at a 400 to 4000 nit.

In addition, according to Table 1, it can be seen that lifetime of the white OLEDs according to the embodiments of the present invention is longer than lifetime of the white OLEDs according to the comparative examples. The white OLEDs according to the embodiments of the present invention had a high current efficiency of about 14 (cd/A) and a high quantum efficiency of about 7.25 to 8.15(%).

The embodiments of the present invention are directed to a white OLED including the HBL. However, the present invention can be applied to any white OLED which does not include the HBL. In this case, a CSL is included to reduce mobility change according electric field caused not by the HBL but by the ETL. Here, a mobility change ratio of the CSL according to electric field may be different from a mobility change ratio of the ETL according to electric field.

The white OLED according to the present invention may be applied in various fields. For example, the white OLED can be applied to various display apparatuses and lighting apparatuses. The application of the present invention is not limited to the white OLED, but includes a full color display apparatus including the white OLED and a color filter, a liquid crystal display apparatus including the white OLED as a back light unit, and a lighting apparatus including the white OLED as a light source. The constitution of the full color display apparatus, the liquid crystal display apparatus, and the lighting apparatus was well known in the art, and thus drawings thereof are omitted.

As described above, the white OLED of the present invention includes a CSL which reduces mobility change according to voltage caused by the HBL and/or the ETL, and thus color change according to applied voltages, i.e., color change according to brightness can be reduced.

In addition, when the CSL is formed under the HBL, the CSL functions as a buffer for the HBL, and thus deterioration of the HBL is inhibited, thereby extending lifetime of the white OLED.

Further, since the CSL inhibits the HBL from being deteriorated in the white OLED of the present invention, and thus color change with respect to time is reduced.

While the present invention has been particularly shown and described with reference to embodiments thereof, it should not be construed as being limited to the embodiments set forth herein but as an exemplary. For example, persons having ordinary skill in the art can easily utilize a two color light emitting layers or other light emitting layers instead of the three color light emitting layer in which the red light emitting layer R, the blue light emitting layer B and the green light emitting layer G are sequentially stacked disclosed in the present invention. Further, positions of the CSL can be varied, and a plurality of the CSLs can be formed. Therefore, the scope of the invention is defined not by the detailed description of the invention but by the following claims.

What is claimed is:

1. A white organic light emitting device, comprising:
an anode;
a hole transporting layer;
a light emitting layer; and
an electron transporting layer and a cathode, wherein at least one color stabilizing layer is interposed between the light emitting layer and the electron transporting layer.

2. The white organic light emitting device of claim 1, wherein a hole blocking layer is interposed between the light emitting layer and the electron transporting layer.

3. The white organic light emitting device of claim 2, wherein the color stabilizing layer is interposed between the light emitting layer and the hole blocking layer.

4. The white organic light emitting device of claim 2, wherein the color stabilizing layer is interposed between the hole blocking layer and the electron transporting layer.

5. The white organic light emitting device of claim 3, wherein the color stabilizing layer is interposed between the hole blocking layer and the electron transporting layer.

6. The white organic light emitting device of claim 1, wherein a mobility change ratio of the color stabilizing layer according to electric field is different from a mobility change ratio of the electron transporting layer according to electric field.

7. The white organic light emitting device of claim 2, wherein a mobility change ratio of the color stabilizing layer according to electric field is different from a mobility change ratio of the electron transporting layer according to electric field.

8. The white organic light emitting device of claim 2, wherein a mobility change ratio of the color stabilizing layer according to electric field is different from a mobility change ratio of the hole blocking layer according to electric field.

9. The white organic light emitting device of claim 1, wherein the color stabilizing layer comprises at least one compound selected from the group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

10. The white organic light emitting device of claim 1, wherein the color stabilizing layer is Alq3 [tris-(8-hydroxy-quinolinato)-aluminum] layer.

11. The white organic light emitting device of claim 1, wherein a charge mobility of the color stabilizing layer is in the range of 10⁻³ to 10⁻⁶ cm²/Vs.

12. The white organic light emitting device of claim 1, wherein a highest occupied molecular orbital (HOMO) level of the color stabilizing layer is in the range of 5.3 to 6.5 eV.

13. The white organic light emitting device of claim 1, wherein a lowest unoccupied molecular orbital (LUMO) level of the color stabilizing layer is in the range of 2.6 to 3.2 eV.

14. The white organic light emitting device of claim 12, wherein a lowest unoccupied molecular orbital (LUMO) level of the color stabilizing layer is in the range of 2.6 to 3.2 eV.

15. The white organic light emitting device of claim 2, wherein the hole blocking layer comprises at least one compound selected from the group consisting of an oxadiazole derivative, a triazole derivative, a phenanthroline derivative, 2,9-Dimethyl-4,7-diphenyl-1,10-phenanhro-line (BCP) and an aluminum complex.

16. The white organic light emitting device of claim 15, wherein the hole blocking layer is Balq [aluminum(III) bis(2-methyl-8-quinolinato) 4-phenylphenolate] layer.

17. The white organic light emitting device of claim 1, wherein a hole injecting layer is further interposed between the anode and the hole transporting layer.

18. The white organic light emitting device of claim 1, wherein an electron injecting layer is further interposed between the cathode and the electron transporting layer.

19. The white organic light emitting device of claim 1, wherein an electron blocking layer is further interposed between the hole transporting layer and the light emitting layer.

20. The white organic light emitting device of claim 1, wherein the hole transporting layer is doped with a p-type impurity.

21. The white organic light emitting device of claim 1, wherein the electron transporting layer is doped with an n-type impurity.

22. A full color display apparatus comprising the white organic light emitting device according to claim 1 and a color filter.

23. A liquid crystal display apparatus comprising the white organic light emitting device according to claim 1 as a backlight unit.

24. A lighting apparatus comprising the white organic light emitting device according to claim 1 as a light source.

25. A white organic light emitting device, comprising:
a transparent substrate;
an anode formed on the substrate;
a hole transporting layer formed on the anode;
an electron blocking layer formed on the hole transporting layer;
a red light emitting layer formed on the electron blocking layer;
a blue light emitting layer formed on the red light emitting layer;
a green light emitting layer formed on the blue light emitting layer;
a color stabilizing layer formed on the green light emitting layer;
a hole blocking layer formed on the color stabilizing layer;
an electron transporting layer formed on the hole blocking layer;
a cathode formed on the electron transporting layer, wherein said color stabilizing layer offsets any charge mobility change of the electron transporting layer and/or the hole blocking layer due to voltage changes.
